(19) United States
(12) Patent Application Publication
(10) Pub. No.: US 2008/0290734 A1
(43) Pub. Date: Nov. 27, 2008

(54) Switching pulse generating circuit and regulator using the same

(75) Inventor: Yoshitaka Nishigata, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 12/149,728

(22) Filed: May 7, 2008

(30) Foreign Application Priority Data
May 25, 2007 (JP) 2007-139357

(51) Int. Cl. H02J 1/00; H03K 3/64; G05F 1/10

(52) U.S. Cl. 307/80; 307/108; 307/106; 323/282

(57) ABSTRACT

A switching pulse generating circuit includes: a load current setting portion to determine the amount of current flowing through a load based on a load current setting signal, the load current setting signal being externally supplied to the load current setting portion, the load current setting signal specifying the amount of current flowing through the load; and a pulse generating portion to output voltage supplying pulses, the output voltage supplying pulses supplying voltage to the load, the pulse width of the voltage supplying pulses being determined based on the load current setting signal.

### BACKGROUND OF THE INVENTION

1. Field of the Invention

The present invention relates to a switching pulse generating circuit, in particular a switching pulse generating circuit used in a regulator producing electrical power or similar device.

2. Description of Related Art

Light emitting diodes (LEDs) are often used for the backlight of a liquid crystal display. The backlight of the liquid crystal display has multiple brightness settings, to each of which the backlight is adjustable. This switching of the brightness is performed by, for example, changing the amount of current flowing through the LEDs. The voltage applied to feed the current through the LEDs is generated by a constant-voltage power supply.

In general, a switching regulator is known as a circuit being configured to produce constant voltage. The switching regulator intermittently feeds electrical current through a coil connected to a load by using a switching element, such as a MOS transistor, the conductivity of which is controlled by switching pulses. Such switching regulator can produce output voltage by the self-induced electromotive force of the coil and the rectification by a diode and a capacitor.

However, in such switching regulator, the power efficiency can fluctuate in response to the fluctuation of the load. Japanese Unexamined Patent Application Publication No. 2003-319643 discloses a method of preventing the deterioration of the power efficiency in such switching regulator by controlling the switching frequency of a transistor which controls current flowing through the coil. Furthermore, Japanese Unexamined Patent Application Publication Nos. 6-303766 (Milton) and 2005-218166 disclose techniques to improve the power efficiency by generating switching pulses by a one-shot pulse generator.

FIG. 6 shows a switching regulator described in Milton. In the switching regulator described in Milton, an N-channel transistor 617 turns on when the output of a comparator 674 which compares VFB with reference voltage is “Low” level and the output of a constant off-period one-shot circuit 625 is “Low” level. The NMOS transistor 617 is driven with one-shot pulses by the constant off-period one-shot circuit 625.

In such case where the output voltage is controlled by using one-shot pulses as switching pulses, the relation between output voltage Vout and time Ton which corresponds to the pulse width of the one-shot pulse is expressed by the following equations.

$$\begin{matrix}{V}_{out} = \frac{{( Vin \times Ton )}^{2}}{2 \times Iout \times ( Ton + Toff )} + Vin & ( 1 ) \\ {IL}_{peak} = \frac{Vin}{L} Ton & ( 2 )\end{matrix}$$

By solving the equation (2) for Ton, it is expressed in the following equation (3).

$$Ton = \frac{L \times {IL}_{peak}}{{V}_{i n}} \qquad ( 3 )$$

By substituting the equation (3) into the equation (1), the following equations (4) and (5) are derived.

$$\begin{matrix}{V}_{out} = \frac{{( Vin \times Ton )}^{2}}{2 \times Iout \times L ( \frac{L \times {IL}_{peak}}{{V}_{i n}} + {T}_{off} )} + Vin & ( 4 ) \\ {V}_{out} = \frac{L \times {IL}_{peak}^{2}}{2 \times Iout \times L ( \frac{L \times {IL}_{peak}}{{V}_{i n}} + {T}_{off} )} + Vin & ( 5 )\end{matrix}$$

Wherein Ton is turn-on time, Toff is turn-off time, Iout is load current, ILₚₑₐₖ is the peak value of current flowing through an inductor element, L is reactance of the inductor element.

As seen from the equation (5), the shorter the turn-off time, the smaller the output voltage value becomes, and the longer the turn-off time, the larger the output voltage value becomes. FIGS. 7A and 7B show relations between the one-shot pulses applied as switching pulses and the output voltage of the switching regulator and the load current flowing through the load. When the amount of current flowing through the load is small, the decrease of the output voltage Vout becomes slow since the discharge of the capacitor connected to the output terminal is slow (see FIG. 7B). On the other hand, when the amount of the load current is large, the decrease of the output voltage becomes fast (see FIG. 7A). Therefore, assuming that the one-shot pulse has constant pulse width, when the load current is large, the turn-off time becomes shorter and the output voltage becomes smaller. On the other hand, when the load current is small, the turn-off time becomes longer and the output voltage becomes larger.

In this way, if the switching is performed with constant pulse width, the ripple of the output voltage becomes larger when the load current is small. The larger ripple of output voltage has been problematic because it increases the average current flowing through the load, and the average load current value exceeds the desired load current value.

### SUMMARY

In accordance with one embodiment of the present invention, a switching pulse generating circuit includes: a load current setting portion to determine the amount of current flowing through a load based on a load current setting signal, the load current setting signal being externally supplied to the load current setting portion, the load current setting signal specifying the amount of current flowing through the load; and a pulse generating portion to output voltage supplying pulses, the output voltage supplying pulses supplying voltage to the load, the pulse width of the voltage supplying pulses being determined based on the load current setting signal.

In accordance with another embodiment of the present invention, a regulator includes: a load current setting portion to determine the amount of current flowing through a load based on a load current setting signal, the load current setting portion being connected to an output terminal; a voltage output portion to produce voltage based on the output from a pulse generating circuit; and the pulse generating circuit to output a pulse signal to the voltage output portion, the pulse width of the pulse signal being determined based on the load current setting signal.

It can reduce the ripple of output voltage by changing the pulse width, and thereby preventing larger current than the desired value from flowing through the load.

It allows current approximately equal to or near the desired current value to flow through the load even when the load current is small.

### BRIEF DESCRIPTION OF THE DRAWINGS

The above and other objects and advantages and features of the present invention will be more apparent from the following description of certain preferred embodiments taken in conjunction with the accompanying drawings, in which:

FIG. 1 is a view showing a switching regulator in accordance with a first embodiment of the present invention;

FIGS. 2A and 2B are views showing switching pulses outputted from the switching pulse generating circuit in accordance with the first embodiment of the present invention, output voltage, and current flowing through the load;

FIG. 3 is a view showing a switching pulse generating circuit in accordance with the first embodiment of the present invention;

FIG. 4 is a view showing a switching pulse generating circuit in accordance with a second embodiment of the present invention;

FIG. 5 is a view showing a switching pulse generating circuit in accordance with another embodiment of the present invention;

FIG. 6 is a view showing a switching regulator described in Milton; and

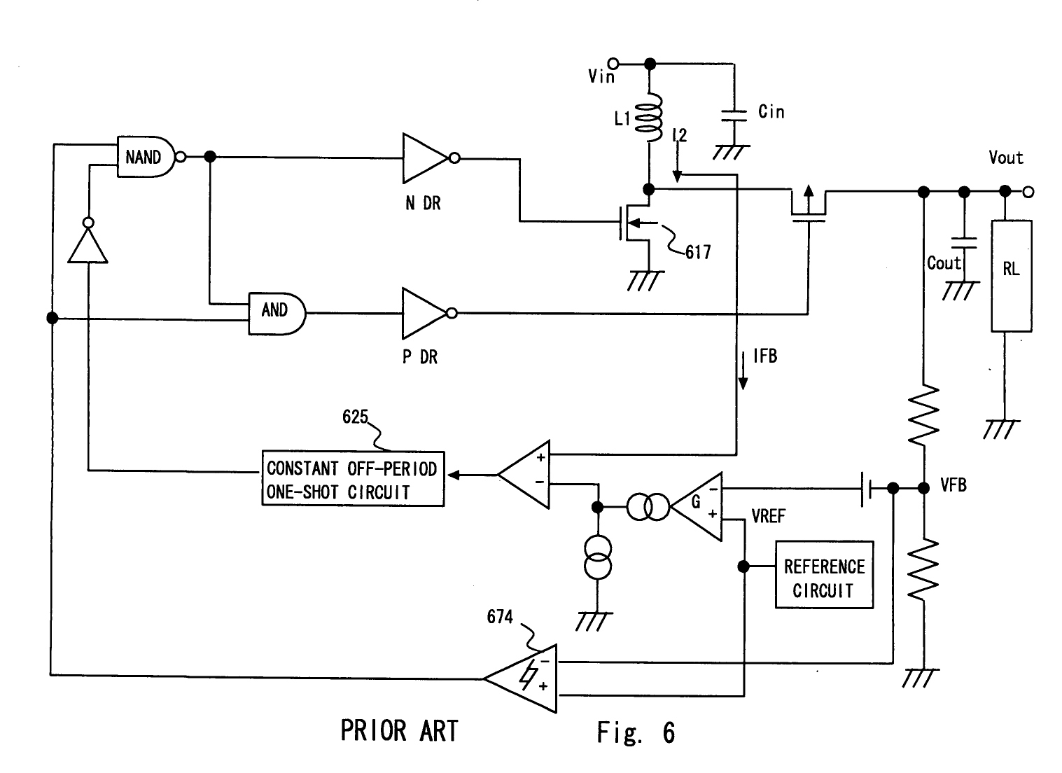

FIGS. 7A and 7B are views showing switching pulses outputted from a switching pulse generating circuit, output voltage, and current flowing through the load when a switching regulator is driven by one-shot pulses.

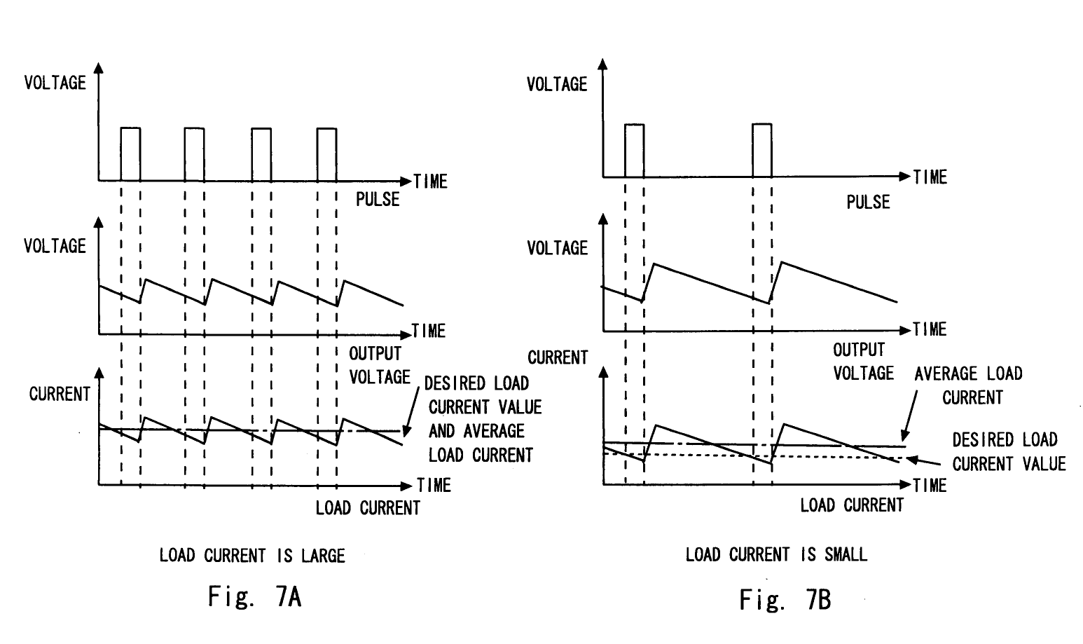

### DETAILED DESCRIPTION OF THE PREFERRED EMBODIMENTS

The invention will now be described herein with reference to illustrative embodiments. Those skilled in the art will recognize that many alternative embodiments can be accomplished using the teachings of the present invention and that the invention is not limited to the embodiments illustrated for explanatory purposes.

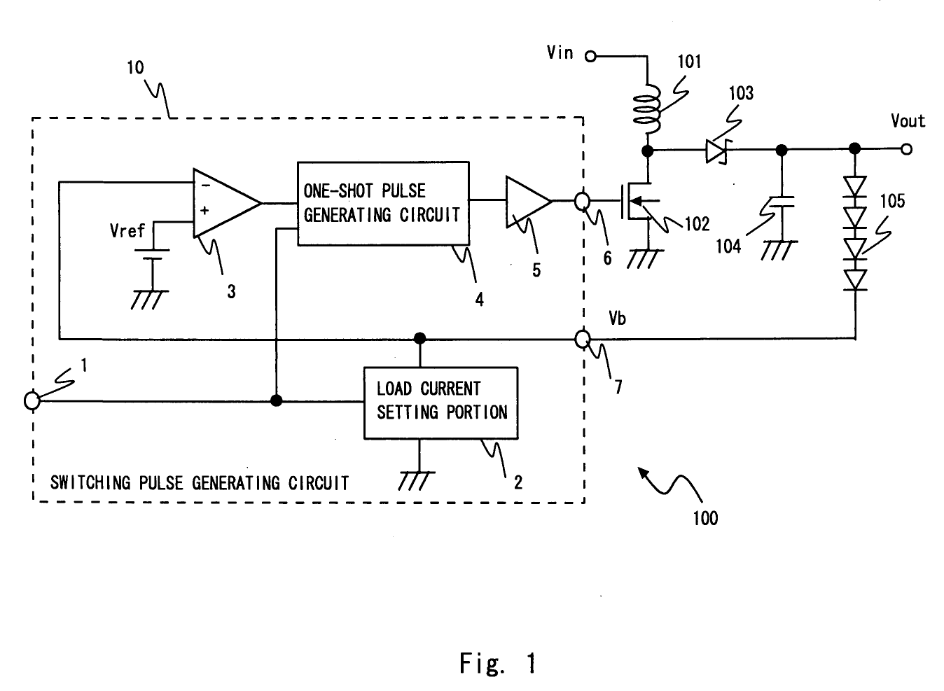

Embodiments in accordance with the present invention are explained hereinafter with reference to the drawings. FIG. 1 shows a switching pulse generating circuit 10 in accordance with a first embodiment of the present invention, and a switching regulator 100 using the switching pulse generating circuit 10.

The switching regulator 100 includes the switching pulse generating circuit 10, a coil 101, an output switching element (NMOS transistor) 102, a diode 103, and a capacitor 104. A load 105 is connected to the output terminal Vout of the switching regulator 100.

Predetermined input voltage is applied to the input terminal Vin. The coil 101 and NMOS transistor 102 which is a switching element are connected in series between the input terminal Vin and ground potential GND. The node between the coil 101 and NMOS transistor 102 is connected to the output terminal Vout through the diode 103. The smoothing capacitor 104 is connected to the output terminal Vout, and the load 105 is connected to the output terminal Vout in parallel with this capacitor 104. This load 105 may be composed of light emitting diodes (LEDs), and for example used for the backlight of a liquid crystal display in this embodiment.

The switching regulator 100 in accordance with this embodiment produces voltage by using self-induced electromotive force which is induced by applying voltage in pulses to the gate of the NMOS transistor 102 to feed current through the coil 101. The output voltage is smoothed by the diode 103 and capacitor 104, and supplied to the load 105. This portion which produces voltage applied to the load corresponds to the voltage output portion.

The switching pulse generating circuit (voltage supplying pulse generating circuit) 10 is a circuit to supply voltage in pulses to the gate of NMOS transistor 102 and establishing the current flowing through the load 105. The switching pulse generating circuit 10 in accordance with the first embodiment of the present invention includes a load current setting terminal 1, a load current setting portion 2, a comparator 3, a one-shot pulse generating portion 4, an output driver 5, a switching pulse output terminal 6, and a load connection terminal 7. In this embodiment, the switching pulse generating circuit 10 is composed of a semiconductor integrated circuit, and formed in a single semiconductor chip.

An external signal which specifies the amount of current flowing through the load is supplied to the load current setting terminal 1. This load current setting signal is supplied, for example, by a user looking at the liquid crystal panel screen, by controlling a switch connected to the load current setting terminal 1 to increase or decrease the brightness of the backlight of the liquid crystal panel screen. Alternatively, the input signal to the load current setting terminal 1 may be changed by the output from a microcomputer which detects the turn of the switch by a user. The load current setting portion 2 is connected to the load 105 through the load connection terminal 7, and establishes the amount of the current flowing through the load 105. In this embodiment, a signal which specifies the brightness of the LEDs is supplied from outside the switching pulse generating circuit 10. The feedback voltage Vb which is in proportion to the current flowing through the load 105 is inputted to the inverting input terminal of the comparator 3, and the reference voltage Vref is inputted to the non-inverting input terminal. The comparator 3 outputs a “High” level signal when the feedback voltage Vb is equal to or less than the reference voltage Vref.

The one-shot pulse generating portion 4 generates a one-shot pulse based on the “High” level output from the comparator 3. The one-shot pulse generating portion 4 in accordance with this embodiment changes the pulse width of the generated one-shot pulse based on the load current setting signal supplied from the load current setting terminal 1. The detail of the one-shot pulse generating portion 4 will be explained later.

The output driver 5 outputs the one-shot pulse generated at the one-shot pulse generating portion 4 from the switching pulse output terminal 6 as the voltage necessary to drive the NMOS transistor 102.

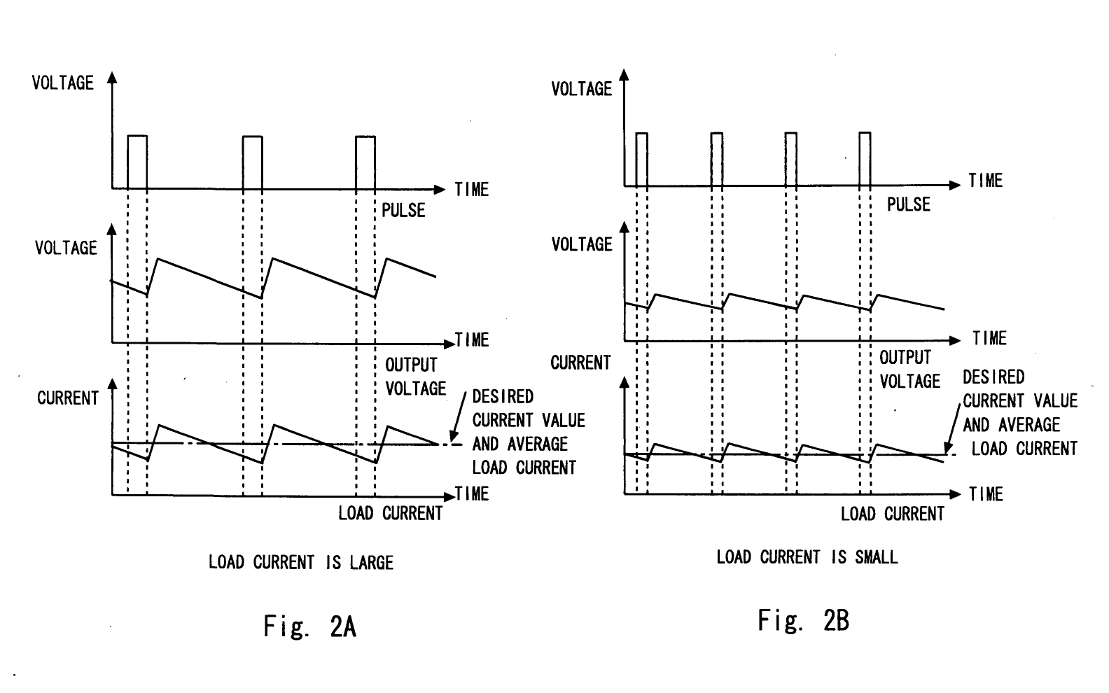

The one-shot pulse generating portion 4 in accordance with this embodiment generates one-shot pulses having different pulse widths to drive the NMOS transistor 102 based on the external load current setting signal. FIGS. 2A and 2B show switching pulses outputted from the switching pulse generating circuit in accordance with this embodiment of the present invention, output voltage, and current flowing through the load. The switching pulse generating circuit 10 in accordance with this embodiment of the present invention outputs pulses having first pulse width as the one-shot pulses when the signal indicates, for example, the decrease of the brightness of LEDs, i.e., the decrease of the load current (FIG. 2B), and outputs pulses having wider pulse width than the first pulse width as the one-shot pulses when the signal indicates the increase of the brightness of LEDs, i.e., the increase of the load current (FIG. 2A).

According to this embodiment, the switching pulse generating circuit 10 shortens the period during which the NMOS transistor 102 is at the on-state when the load current is small. Therefore, it decreases the output voltage, and shortens the amount of time needed for the feedback voltage Vb to decrease to or below the reference voltage Vref. Consequently, it also shortens the interval to the next one-shot pulse which turns on the NMOS transistor 102, and thereby can reduces the ripple and decreases the average load current to the desired current value.

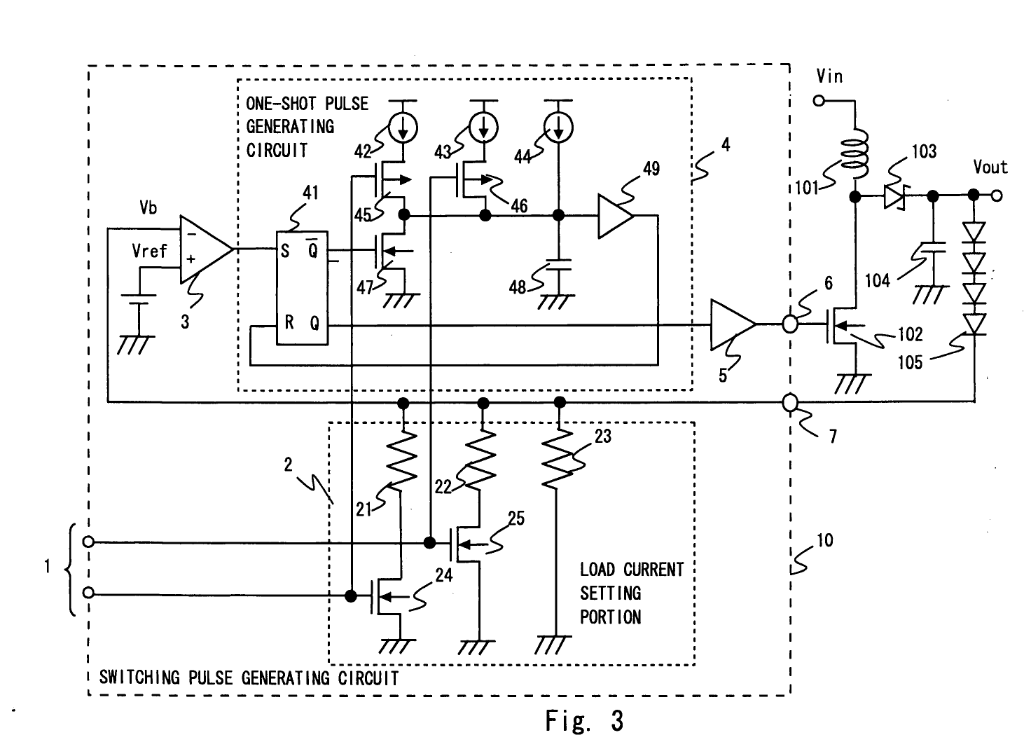

FIG. 3 is a more detailed circuit diagram showing the switching pulse generating circuit 10 in accordance with this embodiment. In FIG. 3, the same signs are assigned to the same components as in FIG. 1, and the explanation of those components is omitted. The one-shot pulse generating portion 4 in accordance with this embodiment includes a RS flip-flop 41, current sources 42-44, PMOS transistors 45 and 46, a NMOS transistor 47, a capacitor 48, and a driver 49.

While the set terminal of the RS flip-flop 41 is connected to the output of the comparator 3, the logical value which is generated by the driver 49 based on the charge accumulated at the capacitor 48 is provided at the reset terminal. The positive output Q of this RS flip-flop is outputted to the output driver 5 to drive the NMOS transistor 102. The current sources 42-44 are connected between the power supply voltage VDD and one electrode of the capacitor 48. The PMOS transistor 45 is connected between the current source 42 and the electrode of capacitor 48, and the PMOS transistor 46 is connected between the current source 43 and the electrode of capacitor 48. A logical value based on the external current value setting signal is inputted to the gates of the PMOS transistors 45 and 46. The PMOS transistors 45 and 46 act as switches controlling the connections between one electrodes of the capacitors and the current sources.

The NMOS transistor 47 is connected between one electrode of the capacitor and ground potential, and the negative output /Q of the RS flip-flop is provided to the gate.

Meanwhile, the load current setting portion 2 is composed of a variable resistor. In the circuit shown in the FIG. 3, it includes resistors 21-23 and NOMS transistors 24 and 25. One ends of the resistors 21-23 are connected to the load 105 through the load connection terminal 7, and the other ends are connected to the ground potential. The NMOS transistor 24 is connected between the resistor 21 and ground potential, and the NMOS transistor 25 is connected between the resistor 22 and ground potential. A logical value based on the current value setting signal is inputted to the gates of the NMOS transistors 24 and 25.

The operation of the switching pulse generating circuit shown in FIG. 3 is explained in detail hereinafter. In switching pulse generating circuit 10 in accordance with this embodiment, a 2-bits logical signal is provided as a load current setting signal. Firstly, a case where “00” is provided as the load current setting signal is explained as an example. When “00” is provided as the load current setting signal, the NMOS transistors 24 and 25 in the load current setting portion 2 become the off-state. Since no current flows through the resistors 21 and 22, the current flowing through the load 105 corresponds to the minimum current.

When the voltage of the output terminal decreases and the feed-backed voltage Vb becomes equal to or less than the reference voltage Vref, a “High” level signal is inputted to the set terminal of the RS flip-flop 41 and the outputs Q and /Q become “High” and “Low” levels respectively. Since the NMOS transistor 47 in the one-shot pulse generating portion 4 turns to the off-state and the PMOS transistors 45 and 46 are at the on-state, the capacitor 48 is charged by three current sources 42, 43, and 44. When the charging of the capacitor 48 advanced and the voltage rose to a certain voltage, the driver 49 outputs a “High” level signal to the reset terminal of the RS flip-flop 41. As the “High” level signal is inputted to the reset terminal, the output Q of the RS flip-flop 41 turns to “Low” level. The amount of time from when the “High” level signal is inputted to the set terminal by the feed-backed voltage Vb to when the “High” level signal is inputted to the reset terminal by the charging of the capacitor corresponds to the signal pulse width shown in FIGS. 2A and 2B.

As explained above, when the load current is set to small value, the charging is performed with the three current sources, and thereby the charging becomes faster and the pulse width becomes narrower.

On the other hand, when “11” is provided as the load current setting signal, the NMOS transistors 24 and 25 in the load current setting portion 2 become the on-state and the PMOS transistors 45 and 46 in the one-shot pulse generating portion 4 become the off-state. In this case, the load current corresponds to the maximum current value. Similarly to the previous case, when the feed-backed voltage Vb decreased, “High” level is inputted to the set terminal and the capacitor 48 is charged. However, when “11” is provided as the load current setting signal, the PMOS transistors 45 and 46 are the off-state and the capacitor is charged by the current source 44 alone. Therefore, assuming that each of the current sources 42-44 can feed the same amount of current, the current supplied to the capacitor is one third of the current of the previous case where “00” is inputted. Therefore, the amount of time before the “High” level signal is inputted to the reset terminal becomes longer, and thereby the pulse width of the one-shot pulse becomes wider.

In this manner, the switching pulses are generated in such manner that the period during which the switching element of the switching regulator is at the on-state is shortened based on the external load current setting signal in this embodiment. For example, in the case of the LEDs of a backlight used in a liquid crystal display, a user may intentionally change the brightness of them during use of the liquid crystal display. In the case where such LEDs or the likes are connected as the load, while the load current is changed based on the signal indicating the amount of the load current, it can prevent the increase of ripple owing to the increase of the output voltage, and control the current flowing through the load such as LEDs to the desired current value by changing the pulse width of the switching pulses.

### Second Embodiment

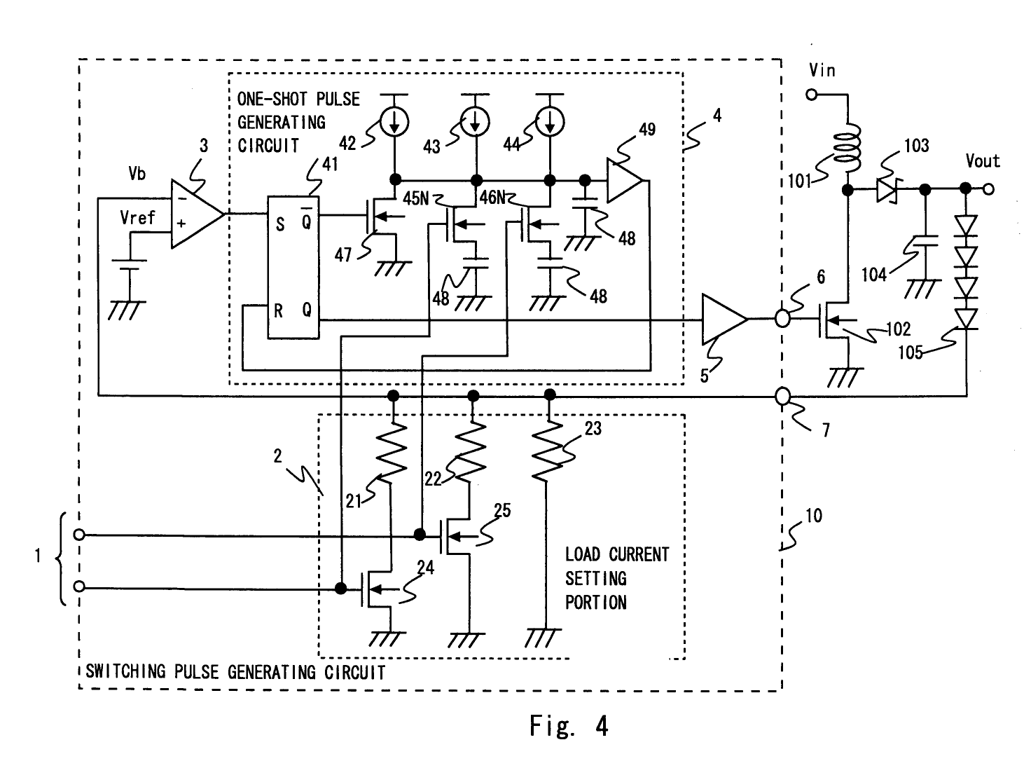

FIG. 4 shows a switching pulse generating circuit 10 in accordance with a second embodiment of the present invention. In FIG. 4, the same signs are assigned to the same components as in FIG. 3, and the explanation of those components is omitted.

The circuit shown in FIG. 4 is different from the circuit shown in FIG. 3 in that a plurality of capacitors 48 and NMOS transistors 45N and 46N connected to the capacitors are provided in the circuit. When the load current is large, the NMOS transistors 45N and 46N become the on-state so that the three capacitors are connected. Therefore, the charging time becomes longer and the pulse width becomes wider. Meanwhile, when the load current is small, the NMOS transistors 45N and 46N become the off-state, and thereby the pulse width can be set to narrower width.

### Other Embodiments

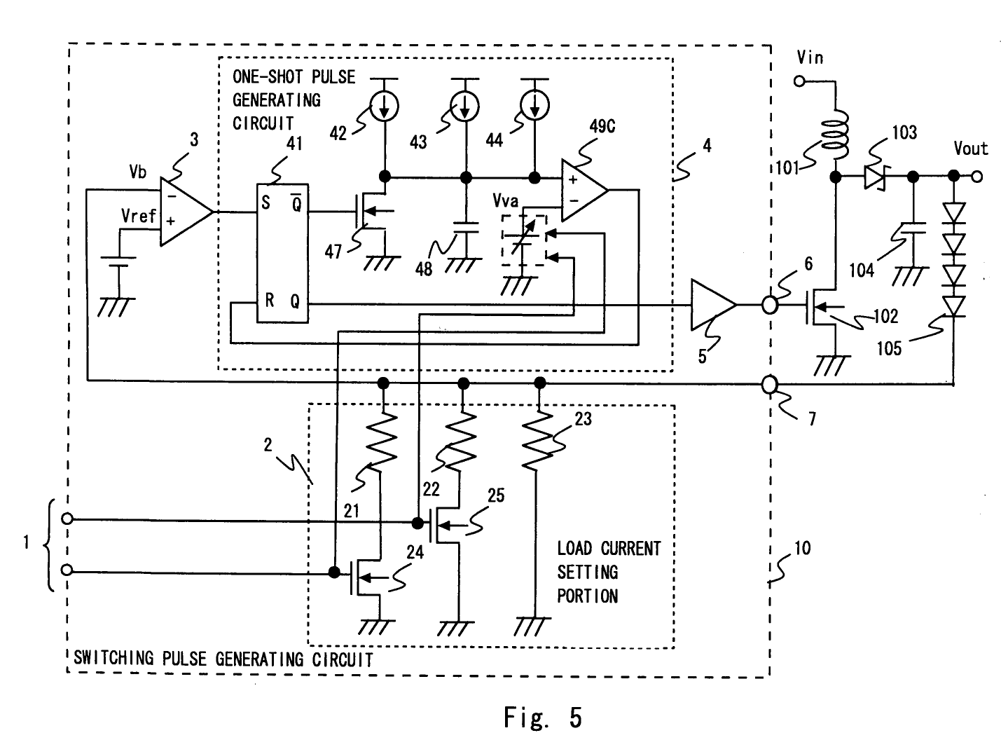

FIG. 5 shows a switching pulse generating circuit 10 in accordance with another embodiment of the present invention. In FIG. 5, the same signs are assigned to the same components as in FIG. 3, and the explanation of those components is omitted. The circuit shown in FIG. 4 is different from the previous circuit in that it has a comparator 49C as a substitute for the driver 49 in the one-shot pulse generating portion 4, and the voltage at one terminal of the capacitor 48 is applied to the non-inverting input terminal of the driver 49C and a variable reference voltage generating portion Vva is connected to the inverting input terminal. The variable reference voltage generating portion Vva in FIG. 5 is a voltage generating portion capable of changing the reference voltage based on the load current setting signal. With this structure, it can change the pulse width of one-shot pulses in similar manner to the other embodiments by setting the output voltage of the variable reference voltage generating portion Vva to smaller value when the load current is small, and to larger value when the load current is large.

Although the present invention is explained with certain embodiments, it should be understood various modifications can be made to the embodiments without departing from the spirit and scope of the present invention. For example, the load current setting portion 2 may use a variable current souse configurable to output current having different current values, instead of the variable resistor. Furthermore, other circuits which are capable of changing the pulse width based on the load current setting signal may be used as a substitute for the one-shot pulse generating portion 4. Furthermore, although the NMOS transistor 102 which feeds current to the coil is formed as a discrete device from the switching pulse generating circuit in the embodiments, this transistor may be formed as a part of a semiconductor integrated circuit and integrated with the switching pulse generating circuit 10 on a single chip.

It is apparent that the present invention is not limited to the above embodiments, but may be modified and changed without departing from the scope and spirit of the invention.

What is claimed is:

1. A switching pulse generating circuit comprising:
a load current setting portion to determine the amount of current flowing through a load based on a load current setting signal, the load current setting signal being externally supplied to the load current setting portion, the load current setting signal specifying the amount of current flowing through the load; and
a pulse generating portion to output voltage supplying pulses, the output voltage supplying pulses supplying voltage to the load, the pulse width of the voltage supplying pulses being determined based on the load current setting signal.

2. The switching pulse generating circuit of claim 1 wherein the pulse generating portion comprises a capacitor, and the switching pulse generation circuit changes current value charged in the capacitor based on the load current setting signal.

3. The switching pulse generating circuit of claim 1 wherein the pulse generating portion comprises a capacitor, and the switching pulse generation circuit changes the capacitance value of the capacitor based on the load current setting signal.

4. The switching pulse generating circuit of claim 1 wherein the pulse generating portion comprises a capacitor and a comparator to compare voltage at one terminal of the capacitor and reference voltage, and the switching pulse generation circuit changes the reference voltage based on the load current setting signal.

5. The switching pulse generating circuit of claim 1 wherein:
the load current setting portion is a variable resistor, the resistance of the variable resistor being changed based on the load current setting signal.

6. The switching pulse generating circuit of claim 2 wherein:
the load current setting portion is a variable resistor, the resistance of the variable resistor being changed based on the load current setting signal.

7. The switching pulse generating circuit of claim 3 wherein:
the load current setting portion is a variable resistor, the resistance of the variable resistor being changed based on the load current setting signal.

8. The switching pulse generating circuit of claim 4 wherein:
the load current setting portion is a variable resistor, the resistance of the variable resistor being changed based on the load current setting signal.

9. The switching pulse generating circuit of claim 2 wherein the pulse generating portion comprise:
a plurality of current sources; and
a switch to control connection between at least one of the plurality of current sources and one electrode of the capacitor based on the load current setting signal.

10. A regulator comprising:
a load current setting portion to determine the amount of current flowing through a load based on a load current setting signal, the load current setting portion being connected to an output terminal;
a voltage output portion to produce voltage based on the output from a pulse generating circuit; and
the pulse generating circuit to output a pulse signal to the voltage output portion, the pulse width of the pulse signal being determined based on the load current setting signal.

11. A switching pulse generating circuit for controlling a regulated voltage of a switching regulator, the switching regulator having an output switching element and an output terminal connected to a load, the switching pulse generating circuit comprising:
a load current setting portion to set the amount of current flowing through the load in response to a load current setting signal;
a pulse generating portion to provide a switching pulse for the output switching element to control the regulated voltage, the pulse width of the switching pulse being responsive to the load current setting signal.

12. The switching pulse generating circuit according to claim 11, wherein larger the amount of current flowing through the load becomes, the longer the pulse width of the switching pulse to turn-on the output switching element becomes.

13. The switching pulse generating circuit according to claim 11, wherein the pulse generating portion includes a control signal and a one-shot pulse generating circuit to generate a one-shot pulse signal as the switching pulse and a comparator to compare a feedback voltage with a reference voltage to trigger the one-shot pulse generating circuit, and the pulse width of the one-shot pulse signal varies in response to the load current setting signal.

14. The switching pulse generating circuit according to claim 13, wherein the one-shot pulse generating circuit includes a capacitor and a plurality of current sources charging the capacitor, at least one of the current sources is selected in response to the load current setting signal to determine the pulse width of the one-shot pulse signal.
